(19) United States
(12) Patent Application Publication
(10) Pub. No.: US 2026/0092951 A1
(43) Pub. Date: Apr. 2, 2026

(54) FOLDABLE TEST BENCH

(71) Applicant: MAGICMOTORSPORT S.R.L., Partinico (IT)

(72) Inventor: Riccardo VASAPOLLI, Carini (IT)

(73) Assignee: MAGICMOTORSPORT S.R.L., Partinico, PA (IT)

(21) Appl. No.: 19/110,411

(22) PCT Filed: Sep. 11, 2023
(86) PCT No.: PCT/IB2023/059001

§ 371 Date: Mar. 10, 2025

(30) Foreign Application Priority Data
Sep. 12, 2022 (IT) 102022000018534

(51) Int. Cl. G01R 1/067

(52) U.S. Cl. CPC G01R 1/06705

(57) ABSTRACT

A foldable test bench comprises a perforated plate or template (2) having a plurality of seats (3) for the positioning of respective probes (4), a supporting structure (5) for the stable positioning of said template (2) on a work surface (P) in at least one raised position with respect thereto, wherein the supporting structure (5) comprises a first articulated arm (10) suitable to connect it to said template (2) and allowing the adjustment of the position of said template (2) with respect to the work surface (P) as well as its positioning in a closed non-operative position.

### TECHNICAL FILED

The present invention finds application within the technical filed of instruments for carrying out tests or mechanical processes and in particular has as its object a foldable test bench of relatively small dimensions suitable for use in connection with one or more tips for carrying out operational tests of electrical and/or electronic circuits or in connection with additional tools for mechanical work on electronic units, such as, for example, welding. The invention also has as its object an assembly comprising the above test bench and one or more test leads suitable for carrying out operational tests on electrical and/or electronic circuits.

### STATE OF THE ART

As known, tests to verify the correct operation of electrical and/or electronic circuits, such as for example printed circuits present on electronic boards, are generally carried out using specific tools that allow specific parameters to be detected.

The most commonly used tools are the so-called testers or multimeters, which allow to check the electrical continuity between the various contacts of the circuit and measure values such as voltage and current intensity, as well as possibly further parameters such as frequency, temperature, electrical capacity, depending on the complexity of the tool and the type of probe used.

Other types of tools, such as voltmeters, ammeters, ohmmeters, allow the detection of a single parameter.

The above tools, of the analog or digital type, are all characterized by the presence of leads or probes suitable for being placed next to respective contacts of the circuit to verify electrical continuity or obtain a specific measurement of the selected parameters, according to methods that may vary depending on the tool.

A first common drawback of the known solutions is represented by the fact that the above tools require the user to constantly support the tips or probes to keep them in contact with the parts of the circuit.

This operating mode, in addition to being particularly uncomfortable, as it requires the constant presence of the operator, can lead to reading errors if the operator does not apply the tip in the correct way or with the right intensity, despite having the perception of acting correctly.

Secondly, the need to manually support the test leads does not allow the application of more than one pair of test leads at a time, which would instead allow for multiple readings on different pairs of contacts.

Last but not least, the probes do not allow the holding force of the contact tip to be adjusted and stabilized on the component of the circuit from which the electrical or electronic signal is taken.

WO2020053782, in the name of the same applicant, discloses a test bench suitable for use in combination with one or more test leads and which solves the above technical problems.

In particular, this test bench has a load-bearing structure provided with a support surface from which a support frame rises which supports a perforated plate or template having a multiplicity of holes for the insertion and support of corresponding test leads or probes, so that it is not necessary to manually support them during the application of the corresponding test leads on the circuits.

The support surface, in addition to allowing the positioning of the tool on the work surface, also constitutes the surface for positioning the circuits to be checked.

The support frame is also provided with an articulated arm which supports a support plate for a probe holder board having a plurality of probes suitable for being placed in contact with the circuits positioned from time to time on the work surface to detect their electrical and/or electronic signal.

This tool, while being effective in allowing the execution of precise tests, allowing the test leads, probes or equivalent means to always be applied correctly and with the right intensity to ensure contact with the parts of the circuit on which to perform the test, presents a relatively rigid structure with relatively large dimensions.

Therefore, there is need for a test bench which, whilst guaranteeing the possibility of carrying out tests on electrical and/or electronic circuits in a precise and effective manner, has small dimensions and which can also be folded up to facilitate transport.

### SCOPE OF THE INVENTION

The object of the present invention is to overcome the above drawbacks by providing a foldable test bench suitable both for carrying out tests on electrical and/or electronic circuits and for mechanical work of various kinds on electronic units, such as electronic boards, and which present reduced dimensions both in the operational phase and when not in use, being adapted to be closed to facilitate both transport and storage. A further object is to provide a foldable test bench that has high flexibility of use, to be used in different positions and in association with different test instruments and/or tools for mechanical processing.

Yet another object is to provide a foldable test bench that may be easily anchored to any support, while always guaranteeing high stability in positioning.

These objects, as well as others which will become more apparent hereinafter, are achieved by a foldable test bench which, according to claim 1, comprises a perforated plate or template having a plurality of seats for the positioning of respective probes and a load-bearing structure for the stable positioning of said template on a work surface in at least one raised position with respect to the work surface.

The supporting structure comprises a first articulated arm designed to connect it to said template and to allow its position to be adjusted with respect to the work surface as well as its positioning in a closed, non-operational position.

In this way, the test bench may have several different configurations for positioning the template, including a compact configuration in which the first articulated arm is folded into the minimum bulk configuration and the template is in a non-operational condition.

Preferably, the template will have a particularly compact size, for example with a maximum overall dimensions in plan of 130*100mm, so that the test bench takes on a particularly compact and with reduced bulk configuration when the first arm is completely folded, to further facilitate its transport and storage.

Furthermore, the test bench may comprise a second articulated arm having a first end connected to said supporting structure and a second free end provided with means for fixing a tool for carrying out tests or other works on electrical and/or electronic circuits.

Advantageously, the tool may be selected from the group comprising the plates equipped with tip-holder cards, vices or pliers for supporting tools and the like.

The test bench will thus take on high versatility, being adapted to be used not only to carry out tests on electrical and electronic circuits but also further workings, such as welding.

Furthermore, the multiple installation methods make precision interventions possible in the most complicated situations, without the need for soldering and possibly even without the need to dismantle the electronic components.

Advantageous embodiments of the invention are obtained in accordance with the dependent claims.

### BRIEF DISCLOSURE OF THE DRAWINGS

Further features and advantages of the invention will be more apparent in light of the detailed description of a preferred but not exclusive embodiment of the foldable test bench according to the invention, illustrated by way of non-limiting example with the aid of the attached drawing tables wherein:

FIG. 1 is a first side view of an assembly for carrying out tests and/or mechanical work on electrical and/or electronic circuits which comprises the foldable test bench;

FIG. 2 is a second side view of the assembly of FIG. 1;

FIG. 3 is a perspective view of the assembly with the foldable test bench in a first operative configuration;

FIG. 4 is a perspective view of the foldable test bench in a second operative configuration;

FIG. 5 is a perspective view of the foldable test bench of FIG. 4 in a different condition of use;

FIG. 6 is a perspective view of the foldable test bench in a third operative configuration.

### BEST MODE OF CARRYING OUT THE INVENTION

The object of the present invention is a foldable test bench particularly suitable for use as a tester or multitester for electrical and/or electronic circuits in combination with a plurality of probes suitable for being connected to a known type tool for measuring and reading the detected parameters, therefore not illustrated.

The subject of the invention is also an assembly for carrying out tests and/or mechanical work on electrical and/or electronic circuits which comprises the foldable test bench and one or more of these probes suitable for being applied to the test bench in a removable manner according to a multiplicity of different distribution schemes.

The type of electrical and/or electronic parameters that can be measured or verified by the assembly will depend on the type of tester or multitester used and the related probes, without particular theoretical limitations.

By way of example and without limitation, through the assembly of a test bench and probes, possibly also of a known type, it will be possible to verify the electrical continuity of one or more portions of a circuit to check the integrity thereof, or carry out measurements of resistance, voltage, capacitance or other electrical or physical quantities or verify the correct transmission of data in the tested electronic circuit.

The type of circuit is not restrictive of the present invention, although preferably the circuit may be a printed circuit provided with a card or other support, such as a PCB. However, as will become clearer from below, the test bench may take on further configurations useful for performing functions other than the typical tester one.

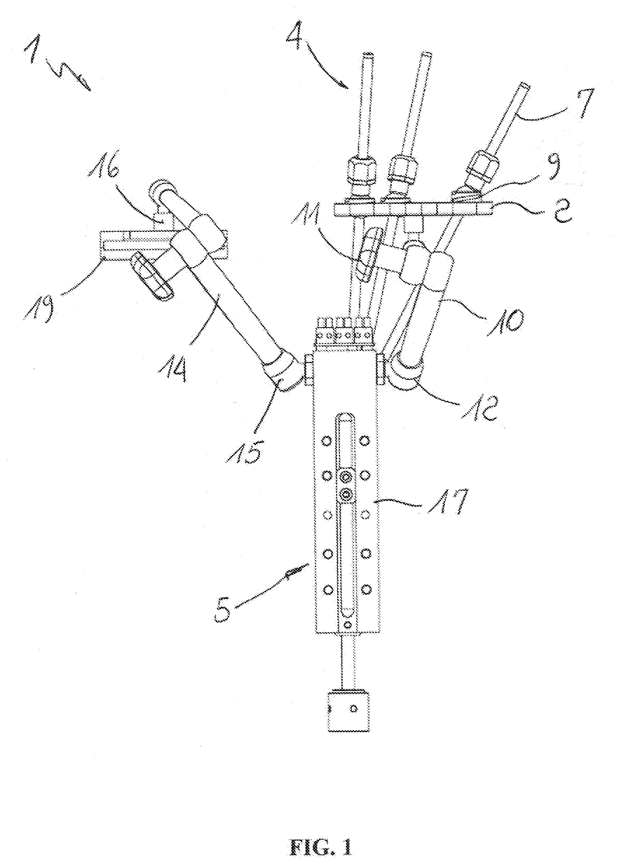

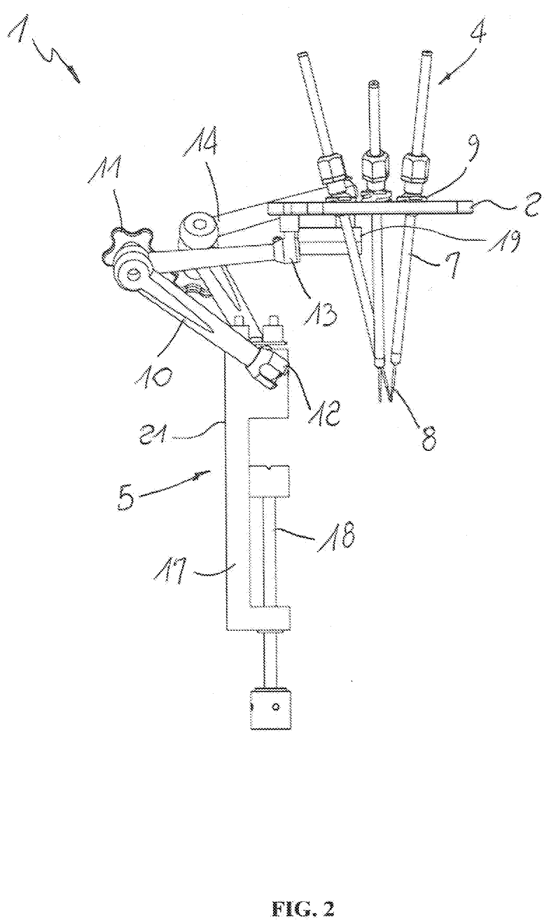

In a preferred but not exclusive configuration, shown in FIGS. 1 and 2, the test bench, indicated globally with 1, comprises a perforated plate or template 2 having a plurality of seats 3 for the positioning of respective probes 4 and a load-bearing structure 5 for the stable positioning of the template 2 on a work surface P in at least one raised position with respect to the work surface itself, so that the template 2 may be positioned above the circuit or circuits C to be checked or treated.

Preferably, the seats 3 of the template 2 will each be defined by a respective through hole made in the template 2.

Each of the holes or seats 3 will then be provided with first coupling means associated with its inner peripheral edge and suitable to cooperate with complementarily shaped second coupling means associated or which can be associated with the probes 4.

The number and dimensions of the through holes 3 are not limiting for the present invention and will also depend on the type of probes used or that can be used.

In particular, when the template 2 is designed for the use of probes of a known type, the holes 3 may have a shape that is substantially complementary to the section of the probe body which will be arranged, in use, inside the hole itself.

As known, in fact, the probes of common testers or multitesters comprise a cylindrical or tubular body 7 provided at one end with a test lead 8 made of conductive material suitable to be placed in contact with a component of the circuit C from which to take the signal and which is connected to the means for measuring and reading the signal by means of connection cables that pass through the cylindrical body.

The coupling means will be designed to allow the connection of one or more probes 4 at a time and their positioning above the work surface P at a height such as to allow contact of the test leads 8 with the components of the circuit C arranged on the work surface P and at which you want to take the electrical and/or electronic signal to carry out the test.

In the illustrated configuration, the probes 4 will hook onto the inner edge of the respective through holes 3 in which they are inserted so as to remain in position with the respective lower test lead 8 in contact with the component of the circuit C arranged under the corresponding hole 3, or even not exactly aligned thanks to the possibility of angulation with respect to the vertical axis and even in the absence of the operator. For example, the coupling means may be of the male and female type and defined by radial protrusions which will fit into corresponding helical grooves made in a disc-shaped coupling element 9 integral with the tubular body 7 of the probe 4 and having an outer diameter substantially equal to the diameter of the through hole 3.

In this way, the locking of the probe 4 in any of the holes 3 will take place by inserting the disc-shaped coupling element 9 and with the subsequent rototranslation thereof inside the selected hole 3.

The latter may also be provided with a further inner annular protrusion which will define an end stroke for the axial translation of the probe 4.

Each probe 4 will also be provided with a joint or spherical joint which will allow it to be inclined with a variable angle, for example with maximum rotation of 25° about its own axis, above the work surface P.

The joint or spherical joint will be arranged at the disc-shaped coupling element 9, which will thus define the rotation point, and will have the purpose of allowing the test lead 8 to also reach components of the circuit which are not perfectly aligned with the center axis of the hole 3 in which the respective probe 4 is inserted.

The supporting structure 5 of the test bench 1 will then comprises a first articulated or jointed arm 10 suitable for connecting it to the template 2 and allowing the adjustment of the position of the latter with respect to the work surface P, as well as its positioning in a non-closed operative position.

In the illustrated configuration, the first articulated arm 10 is composed of two mutually hinged sections so that they can be angled with each other at variable angles, while a clamp 11 placed at the respective common ends will allow their mutual position to be blocked.

In particular, the articulated configuration of the articulated arm 10 will allow it to have 5 degrees of freedom.

Furthermore, a first end 12 of the first articulated arm 10 will be integral or hinged to the supporting structure 5, while a second end 13 will be integral or hinged to the template 2.

The supporting structure 5 is also provided with a second articulated arm 14, also with 5 degrees of freedom and composed of two sections in the illustrated configuration and with a structure similar to that of the first arm 10.

The second articulated arm 14 has a first end 15 connected to the supporting structure 5 and a free second end 16 provided with means for fixing a tool for carrying out tests or other work on electrical and/or electronic circuits, as described more detail later.

The stable positioning of the bench 1 on the work surface P may take place according to different methods, as visible from FIGS. from 3 to 6.

In particular, first of all the supporting structure 5 will be provided with means for stable but removable anchoring to the work surface.

For example, the first anchoring means may comprise a vice 17 provided with removable fixing means 18 to the work surface, which may be of the spring screw type or any other known type.

The first articulated arm 10 will extend from the vice 17, to which it will be hinged at its first end 12, to keep the template 2 in the raised position on the work surface, as well as to allow it to be closed in a compact position.

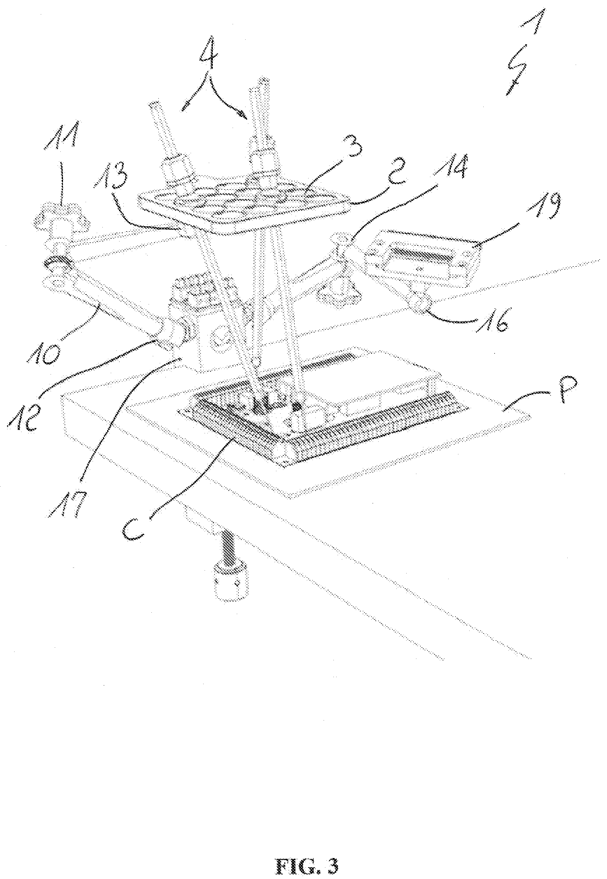

FIG. 3 shows a typical configuration of use of the test bench 1 anchored to a work surface P by means of the vice 17 to use the template 2 in association with a plurality of probes 4.

The second articulated arm 14 is instead associated with a coupling plate 19 having a seat for housing a test lead card provided with a plurality of test leads suitable for detecting the electrical and/or electronic signal from the circuit to be tested and which they protrude from one of its faces to be placed in contact with the components of the circuit present on the support surface.

Advantageously, the leads may be distributed according to an arrangement that reproduces that of the contacts of the circuit to be tested.

To this end, it will be possible to use for each test a special card created by applying the leads in a fixed manner on the card according to the selected configuration.

Alternatively, it is always possible use the same support board on which the leads may be applied in a removable manner to be moved and rearranged according to needs.

Regardless of the configuration of the leads holder board, the latter will be equipped with a circuit for the electrical and/or electronic connection of the leads to the external tool for measuring and reading the parameters.

This circuit, not visible from the figures, will be provided with contact terminals at the output, also not visible from the figures, which will connect to a contact block present on the coupling plate and which in turn will be connected to the measuring tool by electrical and/or electronic connection means, for example cables or buses for the passage of electrical and/or electronic signals.

The fixing of the coupling plate 19 to the supporting structure 5 is made adjustable thanks to the presence of the second articulated arm 14 which allows it to be moved in the space with respect to the support and work surface P according to at least three degrees of freedom, preferably five, as well as the positioning of the coupling plate 19 also in an inclined position with respect to the support surface P.

The position of the second articulated arm 14 will also be adjustable in height to adjust the height of the tip holder board with respect to the support surface P, based on the size of the leads 8 and/or the circuit components.

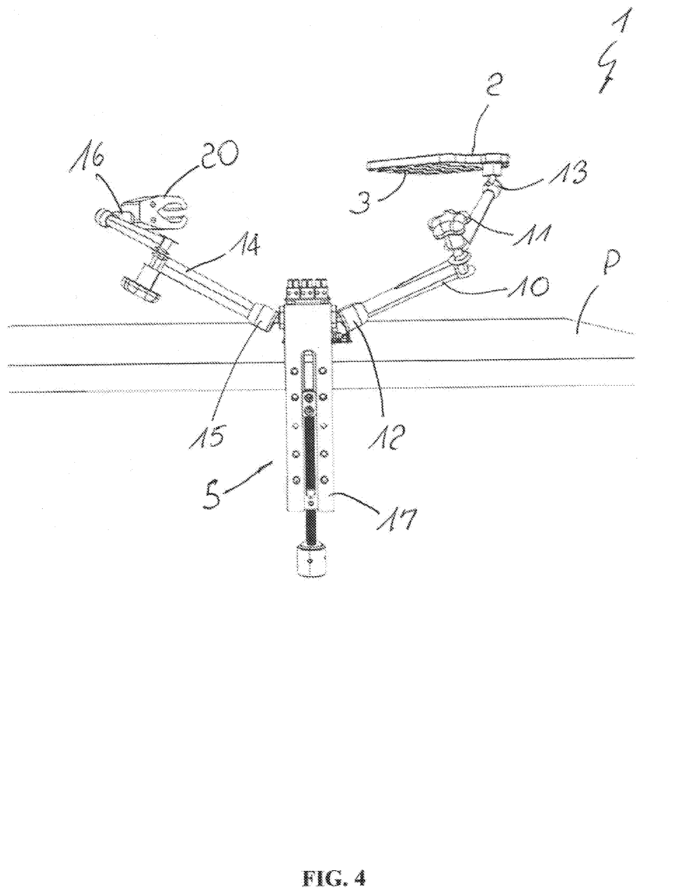

FIG. 4, however, shows a second configuration of the test bench 1 wherein the tool associated with the second end 16 of the second articulated arm 14 are pliers 20 for supporting a further tool, for example a welding tool, not illustrated, or other tool for carrying out mechanical work on the circuit present on the support surface.

However, it is understood that it will also be possible to use other tools in this configuration, such as handling tools, or not to use tools, without particular limitations.

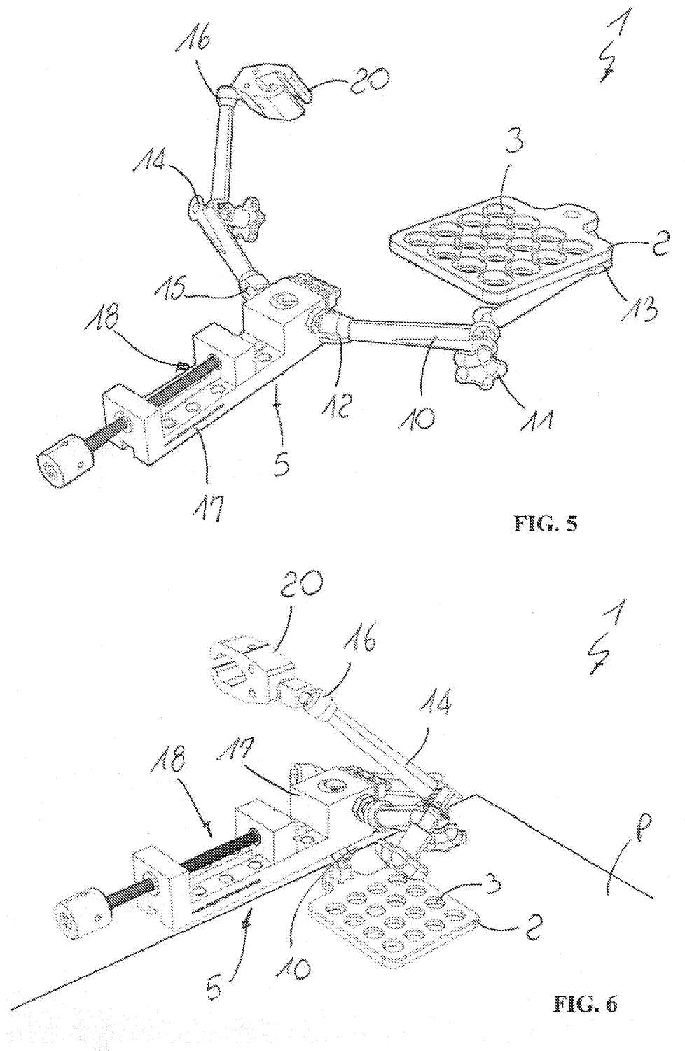

FIG. 5 instead shows a different way of using the test bench in the second configuration of use, wherein the positioning will take place by placing the vice 17 on the work surface P.

To this end, the same vice 17 will be suitably prismatic in shape with at least one flat face 21 which will define a support surface suitable for being positioned on the work surface P and used as an alternative to the fixing means for positioning the template 2 above the work surface P.

FIG. 6 shows a third operating mode wherein the template 2, having a flat shape, is used as an auxiliary and alternative support surface to the support surface 21 of the vice 17.

In this case, the second foldable arm 14 will support a tool, for example the pliers 20 described above, while the vice 17 will be raised to possibly house a component on which to perform processing using the tool supported by the pliers 20.

To facilitate the replacement of the tools applied from time to time to the second articulated arm 14, the latter will be suitably provided with first coupling means, possibly of the quick coupling type, for the tools at its second end 16.

In turn, the tools of the suitably prepared group will be provided with respective second coupling means complementary to the first coupling means for their removable and selective fixing to the second articulated arm 14.

The second coupling means of the various tools will not necessarily be the same as each other, as long as they are suitable for coupling to the same first coupling means.

1-12. (canceled)

13. A foldable test bench for use with one or more probes having test leads for the detection of one or more parameters of a circuit by contacting components of the circuit with the test leads, the test bench comprising:
a plate selected from the group consisting of a perforated plate and a perforated template having a plurality of seats for the removable positioning of the one or more probes; and
a supporting structure for the stable positioning of the plate on a work surface in at least one raised position with respect thereto;
wherein the supporting structure comprises a first articulated arm adapted to connect it to the plate and to allow the adjustment of the position of the plate over the work surface and in a folded non-operative position.

14. The foldable test bench of claim 13, wherein the supporting structure includes fixing means to removably hold the supporting structure in a stable, anchoring position to the work surface; and wherein the first articulated is designed to hold the plate in a raised position on the work surface.

15. The foldable test bench of claim 14, wherein the supporting structure is provided with a support surface adapted to be positioned on the work surface and used as an alternative to the fixing means for positioning the template on the work surface.

16. The foldable test bench of claim 14, wherein the supporting structure includes a vice provided with both the fixing means and the support surface.

17. The foldable test bench of claim 15, wherein the supporting structure includes a vice provided with both the fixing means and the support surface.

18. The foldable test bench of claim 16, wherein a second articulated arm has a first end connected to the supporting structure and a free second end having means for fixing a tool for testing at least one of an electrical circuit and an electronic circuit.

19. The foldable test bench of claim 17, wherein a second articulated arm has a first end connected to the supporting structure and a free second end having means for fixing a tool for testing at least one of an electrical circuit and an electronic circuit.

20. The foldable test bench of claim 19, wherein the tool is selected from the group consisting of plates provided with tip-holder card, pliers for supporting tools, and handling tools.

21. The foldable test bench of claim 20, wherein the second articulated arm is provided with first coupling means for the tools at a second end with the tools including second coupling means complementarily shaped with respect of the first coupling means for removable and selective fixing to the second articulated arm.

22. The foldable test bench of claim 21, wherein t the template is flat for use as an auxiliary resting surface alternative to the support surface of the supporting structure.

23. The foldable test bench of claim 22, wherein the first articulated arm has a first end hinged to the vice and a second end hinged to the template for holding the vice in a raised position above the work surface when the template is used as a support surface.

24. The foldable test bench of claim 23, wherein the template is provided with a plurality of through holes defining respective of the seats and each having coupling means associated with its inner peripheral edge and adapted to cooperate with second coupling means of complementary shape to the probes.

25. An assembly for use with a circuit selected from the group consisting of electrical circuits and electronic circuits, comprising:
at least one probe for detecting one or more parameters of the circuit, the at least one probe being provided with a test lead suitable for being placed in contact with one or more components of the circuit;
a test bench that includes
a plate selected from the group consisting of a perforated plate and a perforated template having a plurality of seats for the removable positioning of the at least one probe; and
a supporting structure for the stable positioning of the plate on a work surface in at least one raised position with respect thereto;
wherein the supporting structure has a first articulated arm suitable for connecting to the plate and for allowing the adjustment of the position of the plate over the work surface in a closed non-operative position.

26. The assembly of claim 25, wherein the supporting structure includes fixing means to removably hold the supporting structure in a stable, anchoring position to the work surface; and wherein the first articulated is designed to hold the plate in a raised position on the work surface.

27. The assembly of claim 26, wherein the supporting structure is provided with a support surface adapted to be positioned on the work surface and used as an alternative to the fixing means for positioning the template on the work surface.

28. The assembly of claim 26, wherein the supporting structure includes a vice provided with both the fixing means and the support surface.

29. The assembly of claim 27, wherein the supporting structure includes a vice provided with both the fixing means and the support surface.

30. wherein, wherein a second articulated arm has a first end connected to the supporting structure and a free second end having means for fixing a tool for testing at least one of an electrical circuit and an electronic circuit.

31. The assembly of claim 29, wherein a second articulated arm has a first end connected to the supporting structure and a free second end having means for fixing a tool for testing at least one of an electrical circuit and an electronic circuit.

32. The assembly of claim 31, wherein the tool is selected from the group consisting of plates provided with tip-holder card, pliers for supporting tools, and handling tools.
